(19) United States
(12) Patent Application Publication
(10) Pub. No.: US 2020/0373124 A1
(43) Pub. Date: Nov. 26, 2020

(54) SEMICONDUCTOR PROCESSING APPARATUS

(71) Applicant: Samsung Electronics Co., Ltd., Suwon-si (KR)

(72) Inventors: Junho YOON, Suwon-si (KR); Yonghwan KIM, Suwon-si (KR); Sangwuk PARK, Hwaseong-si (KR); Chanhoon PARK, Osan-si (KR); Hyuk KIM, Seongnam-si (KR); Edward SUNG, Seoul (KR)

(21) Appl. No.: 16/706,773

(22) Filed: Dec. 8, 2019

(30) Foreign Application Priority Data
May 20, 2019 (KR) 10-2019-0059135

(51) Int. Cl. H01J 37/32

(52) U.S. Cl. CPC H01J 37/32082; H01L 21/31144; H01J 2237/334

(57) ABSTRACT

A semiconductor processing apparatus includes an upper electrode and a substrate on a lower electrode disposed inside the process chamber, a first power generator configured to provide a low-frequency signal to the lower electrode, wherein the low-frequency signal varies between a reference voltage and a first voltage at intervals of a first cycle, a second power generator configured to provide a high-frequency signal to the lower electrode, wherein the high-frequency signal has a sinusoidal waveform that oscillates at intervals of a second cycle shorter than the first cycle, and a direct-current (DC) power generator configured to provide a DC bias to the upper electrode. The high-frequency signal is turned off during at least part of a duration for which the low-frequency signal has the first voltage, and the high-frequency signal is turned on and turned off at intervals of a third cycle different from the first and second cycles.

### CROSS-REFERENCE TO RELATED APPLICATION

This application claims the benefit of Korean Patent Application No. 10-2019-0059135, filed on May 20, 2019, in the Korean Intellectual Property Office, the disclosure of which is incorporated herein in its entirety by reference.

### BACKGROUND

The inventive concept relates to a semiconductor processing apparatus. More particularly, the inventive concept relates to a semiconductor processing apparatus using plasma.

Semiconductor devices may be formed using various semiconductor manufacturing processes, such as deposition processes, ion implantation processes, photolithography processes, and etching processes. With an increase in the integration density of semiconductor devices, linewidths of patterns in the semiconductor devices have been reduced, and aspect ratios of the patterns have increased. The difficulty of a semiconductor manufacturing process has gradually increased due to the reduction in the linewidths and/or the increase in the aspect ratios. Thus, research has been conducted into various methods for forming microstructures having high aspect ratios with high reliability.

### SUMMARY

The inventive concept provides a semiconductor processing apparatus having enhanced reliability.

Aspects of the inventive concept should not be limited by the above description, and other unmentioned aspects will be clearly understood by one of ordinary skill in the art from example embodiments described herein.

According to an aspect of the inventive concept, there is provided a semiconductor processing apparatus including a process chamber in which a semiconductor process is performed, a lower electrode disposed inside the process chamber, the lower electrode having a top surface on which a substrate is loaded, an upper electrode disposed on the lower electrode, a first power generator configured to provide a low-frequency signal to the lower electrode, wherein the low-frequency signal varies between a reference voltage and a first voltage lower than the reference voltage at intervals of a first cycle, a second power generator configured to provide a high-frequency signal to the lower electrode, wherein the high-frequency signal has a sinusoidal waveform that oscillates at intervals of a second cycle shorter than the first cycle, and a direct-current (DC) power generator configured to provide a DC bias to the upper electrode, wherein the DC bias is lower than the reference voltage. The high-frequency signal is turned off during at least part of a duration for which the low-frequency signal has the first voltage. The high-frequency signal is turned on and turned off at intervals of a third cycle different from the first and second cycles.

According to another aspect of the inventive concept, there is provided a semiconductor processing apparatus including a process chamber having an inner space configured to perform a process using plasma, a lower electrode located inside the process chamber, the lower electrode having a top surface configured to mount a substrate thereon, an upper electrode located on the lower electrode, a first power generator configured to provide, over a first cycle, a reference voltage to the lower electrode during a first duration and provide a radio-frequency (RF) sinusoidal signal to the lower electrode during a second duration, a second power generator configured to provide, over a second cycle, a first voltage to the lower electrode during a third duration and provide the reference voltage to the lower electrode during a fourth duration, and a direct-current (DC) power generator configured to apply a DC bias to the upper electrode, wherein the DC bias is lower than the reference voltage. The first cycle is repeated, the second cycle is repeated, and the second duration overlaps about 4% to about 95% of the fourth duration.

According to another aspect of the inventive concept, there is provided a semiconductor processing apparatus including a process chamber in which a semiconductor process is performed, a lower electrode disposed inside the process chamber, the lower electrode having a top surface on which a substrate is loaded, an upper electrode disposed on the lower electrode, a first power generator configured to provide provide a high-frequency signal to the lower electrode, the high-frequency signal turned off during a first duration and turned on during a second duration, a second power generator configured to provide a low-frequency signal to the lower electrode, the low-frequency signal turned on during a third duration and turned off during a fourth duration, and a direct-current (DC) power generator configured to provide a DC bias to the upper electrode, wherein the DC bias is lower than a reference voltage. The first power generator is configured to provide a reference voltage to the lower electrode during the first duration and provide the high-frequency signal to the lower electrode during the second duration. The second power generator is configured to provide a first voltage lower than the reference voltage to the lower electrode during the third duration and provide the reference voltage to the lower electrode during the fourth duration. The first duration is synchronous with the third duration and a length of the first duration is the same as a length of the third duration.

### BRIEF DESCRIPTION OF THE DRAWINGS

Embodiments of the inventive concept will be more clearly understood from the following detailed description taken in conjunction with the accompanying drawings in which:

FIG. 1A is a schematic diagram of a semiconductor processing apparatus according to example embodiments;

FIG. 1B is a diagram of a low-frequency power generator, a filter device, and a high-frequency matching device of FIG. 1A, according to an example embodiment;

FIGS. 2A to 2C are schematic diagrams illustrating a semiconductor processing apparatus according to example embodiments;

FIGS. 3 to 12 are graphs illustrating operations of semiconductor processing apparatuses according to example embodiments;

FIG. 13 is a flowchart illustrating a method of manufacturing a semiconductor device, according to example embodiments;

FIGS. 14 to 18 are cross-sectional views illustrating a method of manufacturing a semiconductor device, according to example embodiments;

FIG. 19 is a flowchart illustrating a method of manufacturing a semiconductor device, according to example embodiments; and

FIGS. 20 to 26 are schematic cross-sectional views illustrating a method of manufacturing a semiconductor device, according to example embodiments.

### DETAILED DESCRIPTION OF THE EMBODIMENTS

Hereinafter, embodiments of the inventive concept will be described in detail with reference to the accompanying drawings. The same reference numerals are used to denote the same elements in the drawings, and repeated descriptions thereof will be omitted. In the following drawings, the thickness and size of each layer are exaggerated for clarity and may be slightly different from actual shapes and ratios.

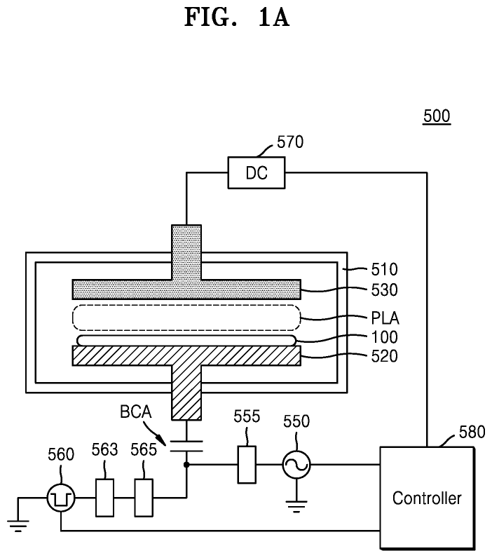

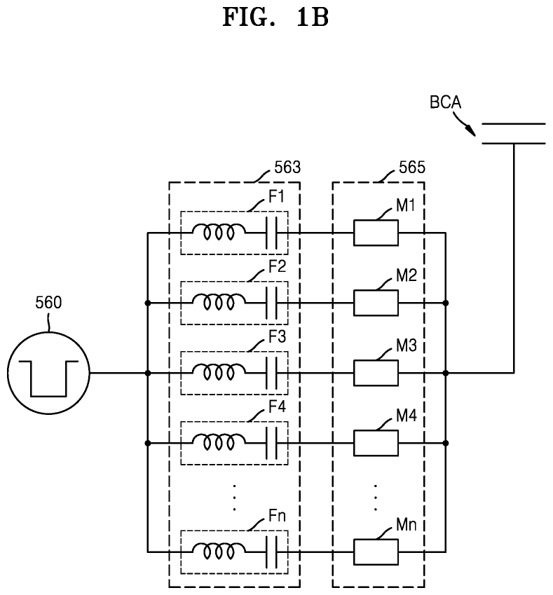

Referring to FIG. 1A, a semiconductor processing apparatus 500 may include a process chamber 510, a lower electrode 520, an upper electrode 530, a high-frequency power generator 550, a low-frequency power generator 560, a high-frequency matching device 555, a filter device 563, a low-frequency matching device 565, a direct-current (DC) power generator 570, and a controller 580.

The process chamber 510 may provide an inner space in which a semiconductor process may be performed. The lower electrode 520 and the upper electrode 530 may be arranged in the process chamber 510. The upper electrode 530 may be arranged on the lower electrode 520. The lower electrode 520 may have a top surface on which a substrate 100 (e.g., a wafer) is loaded.

According to example embodiments, the lower electrode 520 may be an electrostatic chuck. According to example embodiments, the upper electrode 530 may function as a shower head for supplying a process gas into the process chamber 510. According to example embodiments, the upper electrode 530 may function as both a shower head and an electrode used for a semiconductor process. However, the inventive concept is not limited thereto, and the upper electrode 530 may function only as an electrode. When the upper electrode 530 functions only as the electrode, the semiconductor processing apparatus 500 may include an additional gas supply pipe (not shown) or an additional gas supply nozzle (not shown).

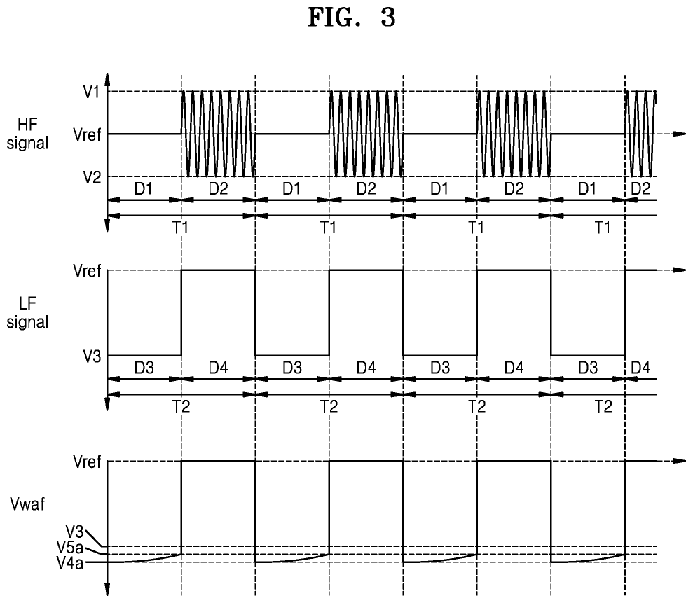

According to example embodiments, the high-frequency power generator 550 may be connected to the lower electrode 520. The high-frequency power generator 550 may generate a high-frequency signal and provide the high-frequency signal to the lower electrode 520 during a semiconductor process. During the semiconductor process, plasma PLA may be generated from the process gas that has been supplied into the process chamber 510 due to the high-frequency signal. The high-frequency signal may be a radio-frequency (RF) signal. The high-frequency signal may be a sinusoidal wave as shown in FIG. 3. According to example embodiments, a frequency of the high-frequency signal may range from about 40 MHz to about 200 MHz, but the inventive concept is not limited thereto. According to example embodiments, a cycle of the high-frequency signal may range from about 0.5 ns to about 2.5 ns, but the inventive concept is not limited thereto.

The low-frequency power generator 560 may be connected to the lower electrode 520. The low-frequency power generator 560 may generate a non-sinusoidal low-frequency signal during a semiconductor process and provide the non-sinusoidal low-frequency signal to the lower electrode 520. The non-sinusoidal low-frequency signal refers to a cycle waveform of a different type from a sinusoidal waveform or a phase-delayed sinusoidal waveform. A frequency of the non-sinusoidal low-frequency signal may be lower than the frequency of the high-frequency signal.

According to example embodiments, the frequency of the non-sinusoidal low-frequency signal may range from about 100 kHz to about 3 MHz. According to example embodiments, the frequency of the non-sinusoidal low-frequency signal may range from about 400 kHz to about 2 MHz.

The non-sinusoidal low-frequency signal may supply energy to plasma PLA. According to example embodiments, the non-sinusoidal low-frequency signal may accelerate ions contained in plasma PLA. The non-sinusoidal low-frequency signal may accelerate ions contained in plasma PLA substantially and constantly. According to example embodiments, since the non-sinusoidal low-frequency signal is a square wave signal, the energy of the plasma PLA may be distributed in a narrow region.

According to example embodiments, the semiconductor processing apparatus 500 may use capacitively coupled plasma (CCP), but the inventive concept is not limited thereto. For example, the semiconductor processing apparatus 500 may use any one of electron cyclotron resonance (ECR) plasma, inductively coupled plasma (ICP), helical plasma, and high-density plasma as plasma.

According to example embodiments, the semiconductor processing apparatus 500 may perform an etching process having a high aspect ratio by using plasma PLA, but the inventive concept is not limited thereto. For example, the semiconductor processing apparatus 500 may perform a process, such as a plasma annealing process, a plasma-enhanced chemical vapor deposition (PECVD) process, a physical vapor deposition (PVD) process, and a plasma cleaning process.

A blocking capacitor BCA may be connected between the low-frequency power generator 560 and the lower electrode 520 and between the high-frequency power generator 550 and the lower electrode 520. The blocking capacitor BCA may convert the non-sinusoidal low-frequency signal into a signal appropriate for an etching process.

The high-frequency matching device 555 may be connected between the blocking capacitor BCA and the high-frequency power generator 550. The high-frequency matching device 555 may improve the transmission efficiency of the high-frequency signal.

The low-frequency matching device 565 may be connected between the blocking capacitor BCA and the low-frequency power generator 560. The filter device 563 may be connected between the low-frequency matching device 565 and the low-frequency power generator 560. Detailed descriptions of the low-frequency matching device 565 and the filter device 563 will be provided below with reference to FIG. 1B.

The DC power generator 570 may be connected to the upper electrode 530. The DC power generator 570 may apply a DC signal to the upper electrode 530 during a semiconductor process (e.g., an etching process). Here, when the DC power generator 570 is referred to as applying the DC signal, the DC signal may vary at intervals of a cycle much longer than those of a high-frequency signal and a non-sinusoidal low-frequency signal. Thus, a frequency of a signal (or a bias voltage) generated by the DC power generator 570 may be much lower than frequencies of the high-frequency signal and the non-sinusoidal low-frequency signal. For example, the frequency of the signal (or the bias voltage) generated by the DC power generator 570 may be about several kHz.

The controller 580 may be connected to the low-frequency power generator 560, the high-frequency power generator 550, and the DC power generator 570. The controller 580 may provide control signals for controlling operations of the low-frequency power generator 560, the high-frequency power generator 550, and the DC power generator 570.

FIG. 1B is a diagram of the low-frequency power generator 560, the filter device 563, and the low-frequency matching device 565 of FIG. 1A, according to an example embodiment.

Referring to FIGS. 1A and 1B, the filter device 563 may include a plurality of band pass filters F1, F2, F3, F4, . . . , and Fn, each of which includes a coil and a capacitor. The respective capacitors included in the band pass filters F1, F2, F3, F4, . . . , and Fn may have different capacitances. The band pass filters F1, F2, F3, F4, . . . , and Fn included in the filter device 563 may decompose a non-sinusoidal low-frequency signal into a plurality of sinusoidal waveform components and output the decomposed sinusoidal waveform components. According to example embodiments, a fast Fourier transformer (FFT) may be connected between the low-frequency power generator 560 and the filter device 563.

The low-frequency matching device 565 may include a plurality of matching boxes M1, M2, M3, M4, . . . , and Mn connected to the band pass filters F1, F2, F3, F4, . . . , and Fn, respectively.

The sinusoidal components respectively output from the band pass filters F1, F2, F3, F4, . . . , Fn may be synthesized and converted into a non-sinusoidal low frequency signal after passing through the matching boxes M1, M2, M3, M4, . . . , and Mn.

Thus, the low-frequency matching device 565 may improve the transmission efficiency of the non-sinusoidal low-frequency signal. The non-sinusoidal low-frequency signal output by the low-frequency matching device 565 may be applied through the blocking capacitor BCA to the lower electrode 520.

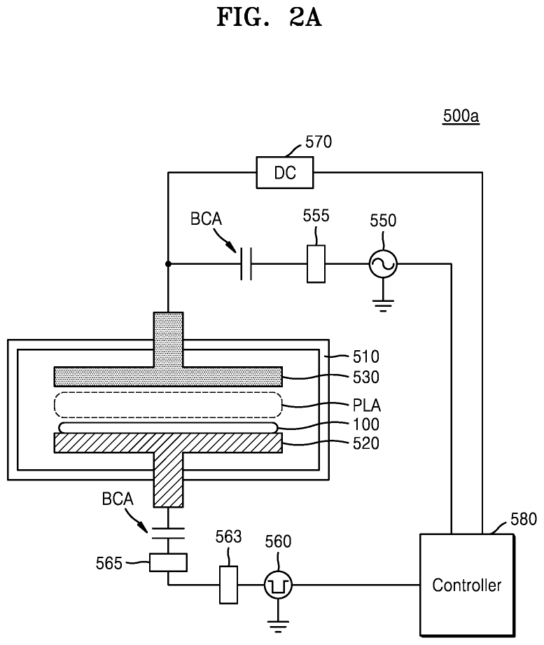

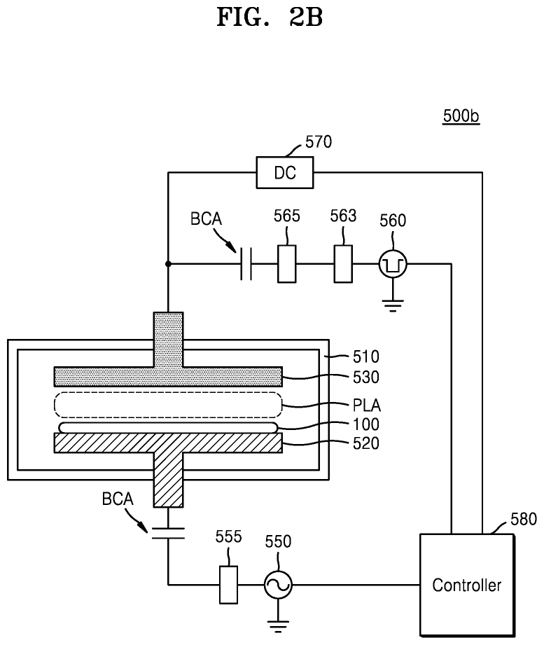

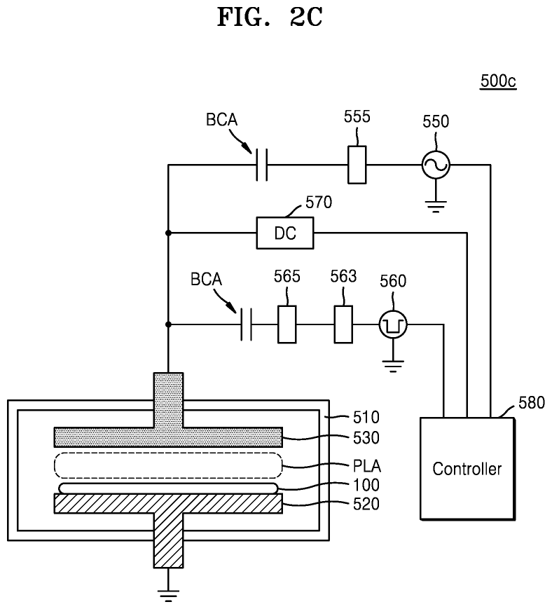

FIGS. 2A to 2C are schematic diagrams illustrating a semiconductor processing apparatus according to example embodiments.

The same descriptions as given with reference to FIG. 1A will be omitted for brevity, and differences will chiefly be described.

Referring to FIG. 2A, a semiconductor processing apparatus 500a may include a process chamber 510, a lower electrode 520, an upper electrode 530, a high-frequency power generator 550, a low-frequency power generator 560, a high-frequency matching device 555, a filter device 563, a low-frequency matching device 565, a DC power generator 570, and a controller 580.

Referring to FIG. 2A, unlike in FIG. 1A, the high-frequency power generator 550 may be connected to the upper electrode 530. Thus, the high-frequency power generator 550 may provide a high-frequency signal to the upper electrode 530. According to example embodiments, plasma PLA may be generated due to the high-frequency signal provided to the upper electrode 530. A blocking capacitor BCA and the high-frequency matching device 555 may be connected between the high-frequency power generator 550 and the upper electrode 530. Ions contained in the plasma PLA may be accelerated due to the non-sinusoidal low-frequency signal provided to the lower electrode 520.

Referring to FIG. 2B, a semiconductor processing apparatus 500b may include a process chamber 510, a lower electrode 520, an upper electrode 530, a high-frequency power generator 550, a low-frequency power generator 560, a high-frequency matching device 555, a filter device 563, a low-frequency matching device 565, a DC power generator 570, and the controller 580.

Referring to FIG. 2B, unlike in FIG. 1A, the low-frequency power generator 560 may be connected to the upper electrode 530. Thus, the low-frequency power generator 560 may provide a non-sinusoidal low-frequency signal to the upper electrode 530. The filter device 563, the low-frequency matching device 565, and a blocking capacitor BCA may be connected between the low-frequency power generator 560 and the upper electrode 530.

Ions contained in the plasma PLA may be accelerated due to the non-sinusoidal low-frequency signal provided to the upper electrode 530. A polarity of the non-sinusoidal low-frequency signal provided to the upper electrode 530 may be opposite to a polarity of the non-sinusoidal low-frequency signal provided to the lower electrode 520 of the semiconductor processing apparatus 500 of FIG. 1A. For example, when the non-sinusoidal low-frequency signal of the semiconductor processing apparatus 500 of FIG. 1A is a square wave that varies between a voltage lower than a reference voltage and the reference voltage, the non-sinusoidal low-frequency signal of the semiconductor processing apparatus 500b of FIG. 2B may be a square wave that varies between a voltage higher than a reference voltage and the reference voltage.

Referring to FIG. 2C, a semiconductor processing apparatus 500c may include a process chamber 510, a lower electrode 520, an upper electrode 530, a high-frequency power generator 550, a low-frequency power generator 560, a high-frequency matching device 555, a filter device 563, a low-frequency matching device 565, a DC power generator 570, and a controller 580.

Referring to FIG. 2C, unlike in FIG. 1A, the high-frequency power generator 550 and the low-frequency power generator 560 may be connected to the upper electrode 530. Thus, the high-frequency power generator 550 may provide a high-frequency signal to the upper electrode 530, and the low-frequency power generator 560 may provide a non-sinusoidal low-frequency signal to the upper electrode 530. A polarity of the non-sinusoidal low-frequency signal provided to the upper electrode 530 may be the same as that described with reference to FIG. 2B. Plasma PLA may be generated due to the high-frequency signal applied to the upper electrode 530, and ions contained in the plasma PLA may be accelerated due to the non-sinusoidal low-frequency signal applied to the upper electrode 530.

FIG. 3 is a graph illustrating an operation of a semiconductor processing apparatus according to example embodiments. Specifically, FIG. 3 is a graph showing signals generated by the high-frequency power generator 550 and the low-frequency power generator 560 of FIG. 1A and a signal applied to a substrate (refer to 100 in FIG. 1A).

Referring to FIG. 3, in sequential order from above, curves show variations in a high-frequency signal (HF signal), a non-sinusoidal low-frequency signal (LF signal), and a voltage Vwaf applied to the substrate 100 with respect to time. In each curve, the abscissa denotes time and the ordinate denotes a voltage. The curves are aligned with each other such that the same positions on the abscissa denote the same time.

Referring to FIGS. 1A and 3, according to example embodiments, a high-frequency signal generated by the high-frequency power generator 550 may be a chopped or pulsed sinusoidal signal. The chopped or pulsed sinusoidal signal may refer to a sinusoidal signal having a predetermined frequency, which is turned on and turned off at a chopping frequency lower than a sinusoidal frequency.

According to example embodiments, the high-frequency signal may be turned on and turned off at intervals of a first cycle T1. The first cycle T1 may include a first duration D1 during which the high-frequency signal is turned off, and a second duration D2 during which the high-frequency signal is turned on. The first duration D1 may be an off duty, and the second duration D2 may be an on duty. According to example embodiments, a length of the first duration D1 is equal to a length of the second duration D2. According to example embodiments, a chopping frequency may range from about 100 kHz to about 3 MHz. According to example embodiments, the chopping frequency may range from about 400 kHz to about 2 MHz. Here, the chopping frequency may be defined as a reciprocal of the first cycle T1.

The high-frequency signal may be turned off during the first duration D1 and have a reference voltage Vref. The reference voltage Vref may be a voltage (e.g., 0 V), which is a basis of other voltages. During the second duration D2, the high-frequency signal may have a sinusoidal voltage having a frequency (e.g., about 40 MHz to about 200 MHz) that is higher than the chopping frequency. The high-frequency signal may be turned on during the second duration D2 and have a sinusoidal voltage that varies between a first voltage V1 and a second voltage V2. The first voltage V1 may be higher than the reference voltage Vref, and the second voltage V2 may be lower than the reference voltage Vref. A difference between the first voltage V1 and the reference voltage Vref may be equal to a difference between the second voltage V2 and the reference voltage Vref, but the inventive concept is not limited thereto.

According to example embodiments, a non-sinusoidal low-frequency signal generated by the low-frequency power generator 560 may be a non-sinusoidal signal (e.g., a square wave) that varies at intervals of a second cycle T2. The second cycle T2 may include a third duration D3 during which the non-sinusoidal low-frequency signal is a third voltage V3 and a fourth duration D4 during which the non-sinusoidal low-frequency signal is the reference voltage Vref. A length of the third duration D3 may be equal to a length of the fourth duration D4.

According to example embodiments, the third voltage V3 may be lower than the reference voltage Vref, but the inventive concept is not limited thereto. For example, as shown in FIGS. 2B and 2C, when the non-sinusoidal low-frequency signal is applied to the upper electrode 530, the third voltage V3 may be higher than the reference voltage Vref.

According to example embodiments, the first duration D1 is the same as the third duration D3. According to example embodiments, the second duration D2 is the same as the fourth duration D4. According to example embodiments, when the non-sinusoidal low-frequency signal is the third voltage V3, the high-frequency signal may be turned off, while, when the non-sinusoidal low-frequency signal is the reference voltage Vref, the high-frequency signal may be turned on. In some examples, the high-frequency signal having the first cycle including a turned on state and a turned off state may be synchronous with the low-frequency signal including the second cycle with a turned off state and a turned on state. In some examples, the first duration may be synchronous with the third duration and a length of the first duration is the same as a length of the third duration.

According to example embodiments, the non-sinusoidal low-frequency signal and the high-frequency signal may alternately have the reference voltage Vref. According to example embodiments, the non-sinusoidal low-frequency signal and the high-frequency signal may alternately have a voltage other than the reference voltage Vref.

According to example embodiments, the semiconductor processing apparatus 500 may be deviated the generation of plasma PLA from the acceleration of ions contained in the plasma PLA on the time axis. According to example embodiments, the semiconductor processing apparatus 500 may temporally separate the generation of the plasma PLA from the acceleration of the ions contained in the plasma PLA. For example, the ions contained in the plasma PLA may not be accelerated during the generation of the plasma PLA, and the plasma PLA may not be generated during the acceleration of the ions contained in the plasma PLA.

According to example embodiments, a voltage applied to the substrate 100 may be determined by the non-sinusoidal low-frequency signal and the high-frequency signal. According to example embodiments, a cycle of a waveform of the voltage applied to the substrate 100 is the same as the first cycle T1 and the second cycle T2. However, the inventive concept is not limited thereto. When the first cycle T1 is different from the second cycle T2, the cycle of the waveform of the voltage applied to the substrate 100 may be the same as a longer one of the first cycle T1 and the second cycle T2 or a least common multiple thereof.

The voltage applied to the substrate 100 may have a roughly square waveform. According to example embodiments, the voltage applied to the substrate 100 may be changed from a fourth voltage V4a to a fifth voltage V5a during the third duration D3 and be the reference voltage Vref during the fourth duration D4. According to example embodiments, the high-frequency signal may be in a turn-off state during the third duration D3 during which ions contained in the plasma PLA are accelerated. Thus, a concentration of the plasma PLA may be reduced, so that the voltage applied to the substrate 100 may have the fourth voltage V4a lower than the third voltage V3 during the transition from the fourth duration D4 to the third duration D3.

According to example embodiments, the ions contained in the plasma PLA may be accumulated on the substrate 100 so that the voltage applied to the substrate 100 may be elevated. According to example embodiments, a variation in the voltage applied to the substrate 100 may increase with time during the third duration D3, but the inventive concept is not limited thereto. The voltage applied to the substrate 100 may be the fifth voltage V5a lower than the third voltage V3 and higher than the fourth voltage V4a at an end of the third duration D3, but the inventive concept is not limited thereto. Depending on an amplitude of the high-frequency signal or the length of the third duration D3, the voltage applied to the substrate 100 may be higher than the third voltage V3 at the end of the third duration D3.

According to example embodiments, the concentration of the plasma PLA may be reduced during the third duration D3, and thus, the variation in the voltage applied to the substrate 100 may be relatively small during the third duration D3. Accordingly, the energy of the ions contained in the plasma PLA that has reached the substrate 100 may be relatively uniform, and the reliability of the semiconductor processing apparatus 500 may be enhanced.

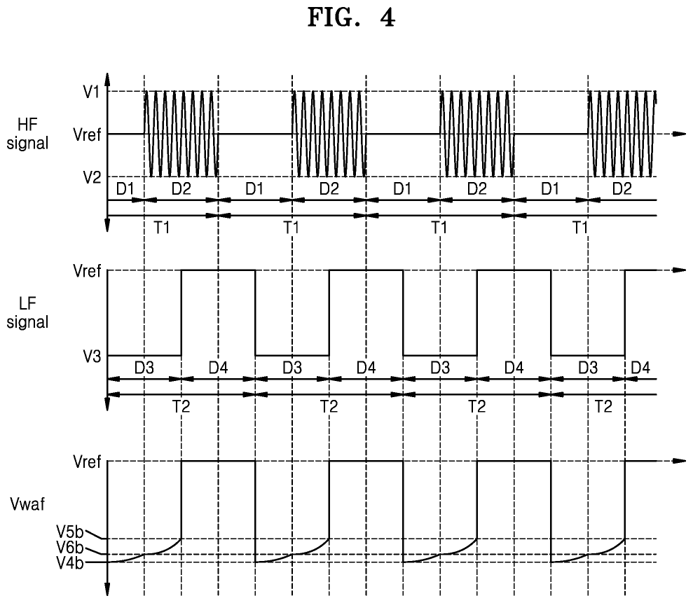

FIG. 4 is a graph illustrating an operation of a semiconductor processing apparatus according to example embodiments. The same descriptions as given with reference to FIGS. 1A and 3 will be omitted for brevity, and differences will chiefly be described.

Referring to FIGS. 1A and 4, a length of a first cycle T1 may be equal to a length of a second cycle T2. According to example embodiments, lengths of first to fourth durations D1 to D4 may be equal to each other.

Although FIG. 4 illustrates a case in which the first and second durations D1 and D2 overlap halves of the third and fourth durations D3 and D4, respectively, the inventive concept is not limited thereto. In an example, a duration for which the first duration D1 overlaps the third duration D3 may be longer or shorter than a duration for which the first duration D1 overlaps the fourth duration D4. In another example, a duration for which the second duration D2 overlaps the third duration D3 may be longer or shorter than a duration for which the second duration D2 overlaps the fourth duration D4.

According to example embodiments, the first duration D1 may overlap each of the third and fourth durations D3 and D4. Thus, while a non-sinusoidal low-frequency signal is maintained at the reference voltage Vref, a high-frequency signal may be switched from a turn-on state to a turn-off state. According to example embodiments, the second duration D2 may overlap each of the third and fourth durations D3 and D4. In an example, the second duration D2 may overlap about 4% to about 95% of the third duration D3. In another example, the second duration D2 may overlap about 4% to about 95% of the fourth duration D4. Thus, while the non-sinusoidal low-frequency signal is maintained at a third voltage V3, the high-frequency signal may be switched from a turn-off state to a turn-on state.

During the fourth duration D4, a voltage applied to a substrate 100 may be substantially constant. According to example embodiments, during the fourth duration D4, the voltage applied to the substrate 100 may be maintained at the reference voltage Vref.

The voltage applied to the substrate 100 may vary during the third duration D3. The voltage applied to the substrate 100 may be changed from a fourth voltage V4b to a sixth voltage V6b during a portion of the third duration D3, which overlaps the first duration D1. The voltage applied to the substrate 100 may be changed from the sixth voltage V6b to a fifth voltage V5b during a portion of the third duration D3, which overlaps the second duration D2.

According to example embodiments, the voltage applied to the substrate 100 may be changed more rapidly during the portion of the third duration D3, which overlaps the second duration D2, than during the portion of the third duration D3, which overlaps the first duration D1. According to example embodiments, a difference between the fourth voltage V4b and the sixth voltage V6b may be smaller than a difference between the sixth voltage V6b and the fifth voltage V5b, but the inventive concept is not limited thereto. The difference between the fourth voltage V4b and the sixth voltage V6b may be greater or smaller than the difference between the sixth voltage V6b and the fifth voltage V5b depending on an extent to which the third duration D3 overlaps the first duration D1.

According to example embodiments, the moment the non-sinusoidal low-frequency signal is changed from the reference voltage Vref to the third voltage V3, that is, when the transition from the fourth duration D4 to the third duration D3 occurs, the high-frequency signal may be in a turn-off state. Thus, the fourth voltage V4b may be lower than the third voltage V3, but the inventive concept is not limited thereto.

According to example embodiments, at a point in time when the high-frequency signal is turned on, that is, at a point in time when the transition from the first duration D1 to the second duration D2 occurs, the voltage applied to the substrate 100 may have a point of inflection. In addition, unlike shown, when the transition from the first duration D1 to the second duration D2 occurs, the voltage applied to the substrate 100 may be discontinuously changed.

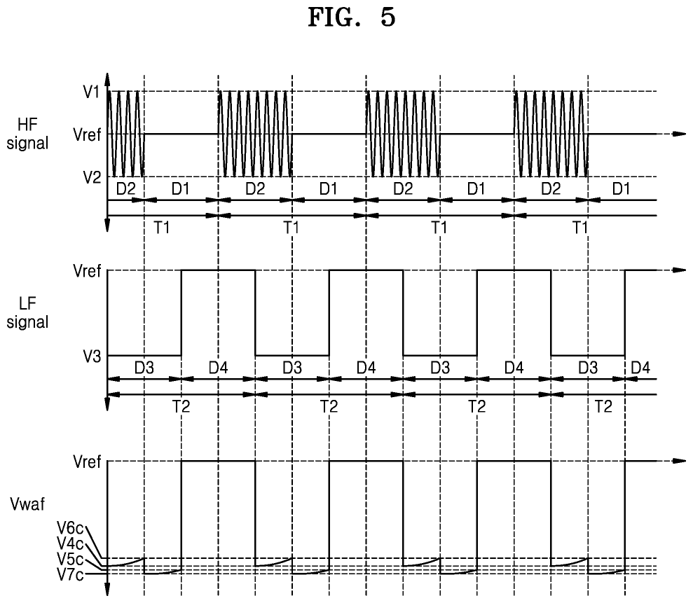

FIG. 5 is a graph illustrating an operation of a semiconductor processing apparatus according to example embodiments. The same descriptions as given with reference to FIGS. 1A, 3, and 4 will be omitted for brevity, and differences will chiefly be described.

Referring to FIGS. 1A and 5, a length of a first cycle T1 may be equal to a length of a second cycle T2. According to example embodiments, lengths of first to fourth durations D1 to D4 may be equal to each other.

According to example embodiments, the second duration D2 may overlap each of the third and fourth durations D3 and D4. In an example, the second duration D2 may overlap about 4% to about 95% of the third duration D3. In another example, the second duration D2 may overlap about 4% to about 95% of the fourth duration D4. Thus, while a non-sinusoidal low-frequency signal is maintained at the reference voltage Vref, a high-frequency signal may be switched from a turn-off state to a turn-on state. The second duration D2 may start during the fourth duration D4 and end during the third duration D3. The fourth duration D4 may be shorter than the second cycle T2. According to example embodiments, the second duration D2 may overlap each of the third and fourth durations D3 and D4. Thus, while the non-sinusoidal low-frequency signal is maintained at a third voltage V3, the high-frequency signal may be switched from a turn-on state to a turn-off state.

During a portion of the third duration D3, which overlaps the second duration D2, a voltage applied to a substrate 100 may be changed from a fourth voltage V4c to a sixth voltage V6c. Although the high-frequency signal is in a turn-on state during the transition from the fourth duration D4 to the third duration D3, the fourth voltage V4c may be lower than the third voltage V3, but the inventive concept is not limited thereto.

When the high-frequency signal is turned off, that is, during the transition from the second duration D2 to the first duration D1, the voltage applied to the substrate 100 may be discontinuously changed. When the high-frequency signal is turned off, the voltage applied to the substrate 100 may be changed from the sixth voltage V6c to a seventh voltage V7c. According to some embodiments, the seventh voltage V7c may be lower than the fourth voltage V4c, but the inventive concept is not limited thereto.

In a portion of the third duration D3, which overlaps the first duration D1, the voltage applied to the substrate 100 may be changed from the seventh voltage V7c to a fifth voltage V5c. According to example embodiments, a variation in the voltage applied to the substrate 100 in the portion of the third duration D3, which overlaps the first duration D1, may be smaller than a variation in the voltage applied to the substrate 100 in the portion of the third duration D3, which overlaps the second duration D2. According to example embodiments, a difference between the fourth voltage V4c and the sixth voltage V6c may be greater than a difference between the seventh voltage V7c and the fifth voltage V5c, but the inventive concept is not limited thereto.

According to example embodiments, during the third duration D3 for which the non-sinusoidal low-frequency signal is the third voltage V3, the high-frequency signal may be turned off so that the voltage applied to the substrate 100 may have a waveform close to a square wave. Thus, an energy distribution of plasma PLA that has reached the substrate 100 may be relatively constant.

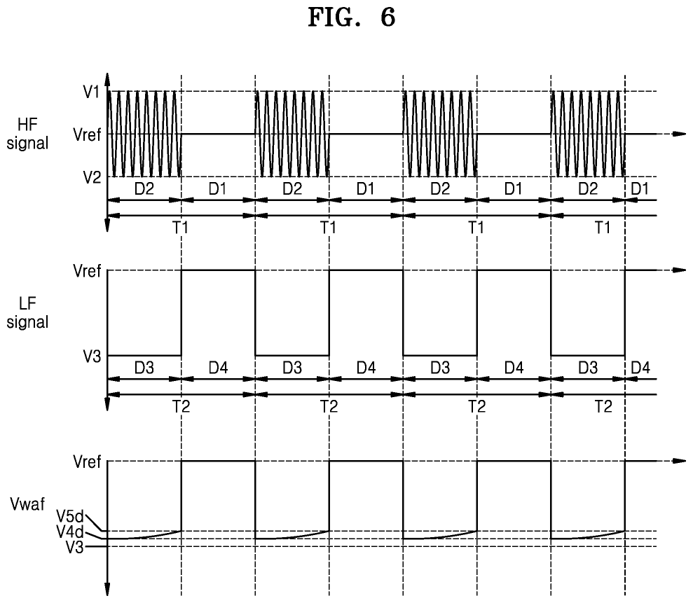

FIG. 6 is a graph illustrating an operation of a semiconductor processing apparatus according to example embodiments. The same descriptions as given with reference to FIGS. 1A and 3 to 5 will be omitted for brevity, and differences will chiefly be described.

According to example embodiments, a first duration D1 may overlap a fourth duration D4 without overlapping a third duration D3. For example, the first duration D1 may be synchronous with the fourth duration D4. Thus, a high-frequency signal may be in a turn-off state during the fourth duration D4 for which a non-sinusoidal low-frequency signal is the reference voltage Vref.

According to example embodiments, a second duration D2 may overlap the third duration D3 without overlapping the fourth duration D4. For example, the second duration D2 may be synchronous with the third duration D3. Thus, the high-frequency signal may be in a turn-on state during the third duration D3 for which the non-sinusoidal low-frequency signal is a third voltage V3.

According to example embodiments, during the third duration D3, a voltage applied to a substrate 100 may be changed from a fourth voltage V4d to a fifth voltage V5d. At a point in time when the third duration D3 starts, since the high-frequency signal is in a turn-on state, the fourth voltage V4d may be higher than the third voltage V3. The fifth voltage V5d may be higher than the fourth voltage V4d. The fifth voltage V5d may be closer to the reference voltage Vref than the fourth voltage V4d.

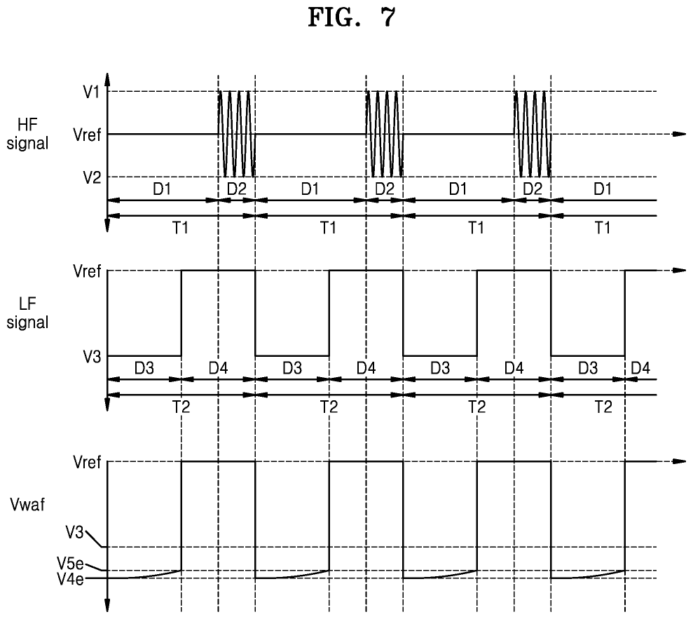

FIG. 7 is a graph illustrating an operation of a semiconductor processing apparatus according to example embodiments. The same descriptions as given with reference to FIGS. 1A and 3 to 6 will be omitted for brevity, and differences will chiefly be described.

Referring to FIGS. 1A and 7, a first cycle T1 may be equal to a second cycle T2. According to example embodiments, a length of a first duration D1 may be different from a length of a second duration D2. According to example embodiments, the length of the first duration D1, which is an off duty of the high-frequency signal, may be greater than the length of the second duration D2, which is an on duty of the high-frequency signal.

The length of the first duration D1 may be greater than a length of each of third and fourth durations D3 and D4. The length of the second duration D2 may be less than the length of each of the third and fourth durations D3 and D4. Although FIG. 7 illustrates a case in which the length of the second duration D2 is about half the length of each of the third and fourth durations D3 and D4 and the length of the first duration D1 is about 3/2 times the length of each of the third and fourth durations D3 and D4, the inventive concept is not limited thereto. A relationship between the lengths of the first to fourth durations D1 to D4 may be variously changed depending on a voltage applied to a substrate 100.

Referring to FIG. 7, the second duration D2 may be included in the fourth duration D4 and overlap the fourth duration D4 without overlapping the third duration D3. Thus, during the fourth duration D4 for which the non-sinusoidal low-frequency signal is maintained at the reference voltage Vref, the high-frequency signal may be turned on and turned off. In addition, during the third duration D3 for which the non-sinusoidal low-frequency signal is maintained at a third voltage V3, the high-frequency signal may be in a turn-off state, but the inventive concept is not limited thereto. For example, depending on a phase of the high-frequency signal, the second duration D2 may be included in the third duration D3 or may overlap each of the third and fourth durations D3 and D4. When the second duration D2 overlaps each of the third and fourth durations D3 and D4, the second duration D2 may overlap a point in time when the transition from the third duration D3 to the fourth duration D4 occurs or overlap a point in time when the transition from the fourth duration D4 to the third duration D3 occurs.

According to example embodiments, a voltage applied to the substrate 100 may be maintained at the reference voltage Vref during the fourth duration D4 and increase during the third duration D3. When the third duration D3 starts, that is, when the application of the third voltage V3 starts, since the high-frequency signal is in a turn-off state, the voltage applied to the substrate 100 may be lower than the third voltage V3.

According to example embodiments, since the length of the second duration D2 is less than the length of the first duration D1, a concentration of ions contained in plasma PLA may be relatively low. Thus, a fourth voltage V4e of FIG. 7 may be lower than the fourth voltage V4a of FIG. 3. In an example, a fifth voltage V5e of FIG. 7 is lower than the fifth voltage V5a of FIG. 3. Also, a variation in the voltage applied to the substrate 100 during the third duration D3 shown in FIG. 7 may be smaller than a variation in the voltage applied to the substrate 100 during the third duration D3 shown in FIG. 3. A difference between the fourth voltage V4e and a fifth voltage V5e in FIG. 7 may be smaller than a difference between the fourth voltage V4a and the fifth voltage V5a in FIG. 3.

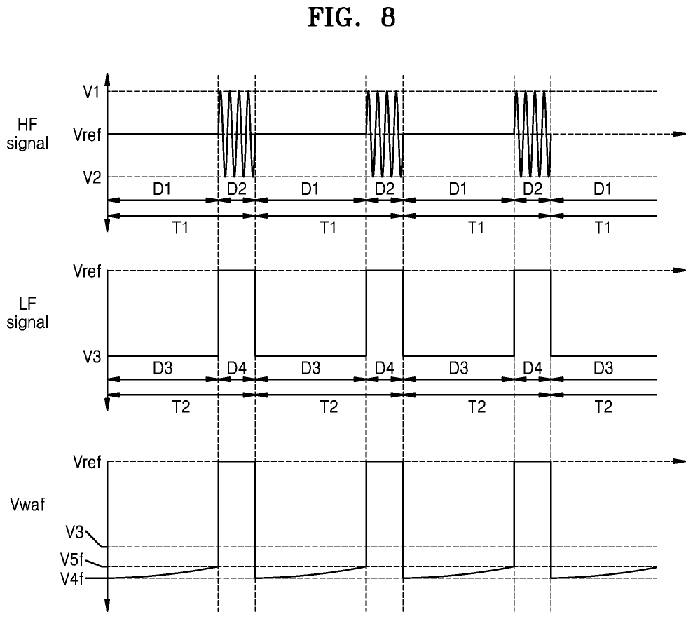

FIG. 8 is a graph illustrating an operation of a semiconductor processing apparatus according to example embodiments. The same descriptions as given with reference to FIGS. 1A and 3 to 7 will be omitted for brevity, and differences will chiefly be described.

Referring to FIGS. 1A and 8, a high-frequency signal may be substantially equal to the high-frequency signal described with reference to FIG. 7.

According to example embodiments, a length of a third duration D3 may be different from a length of a fourth duration D4. According to example embodiments, the length of the third duration D3 for which a non-sinusoidal low-frequency signal is maintained at a third voltage V3 may be greater than the length of the fourth duration D4 for which the non-sinusoidal low-frequency signal is maintained at the reference voltage Vref.

According to example embodiments, the length of the third duration D3 may be equal to a length of a first duration D1, and the length of the fourth duration D4 may be equal to a length of a second duration D2.

Referring to FIG. 8, the first duration D1 may overlap the third duration D3 without overlapping the fourth duration D4, and the second duration D2 may overlap the fourth duration D4 without overlapping the third duration D3, but the inventive concept is not limited thereto. For example, depending on a phase of the high-frequency signal, the second duration D2 may be included in the third duration D3 or may overlap each of the third and fourth durations D3 and D4.

A voltage applied to a substrate 100 during the third duration D3 may be changed from a fourth voltage V4f to a fifth voltage V5f. According to example embodiments, the fifth voltage V5f of FIG. 8 may be higher than the fifth voltage V5e of FIG. 7.

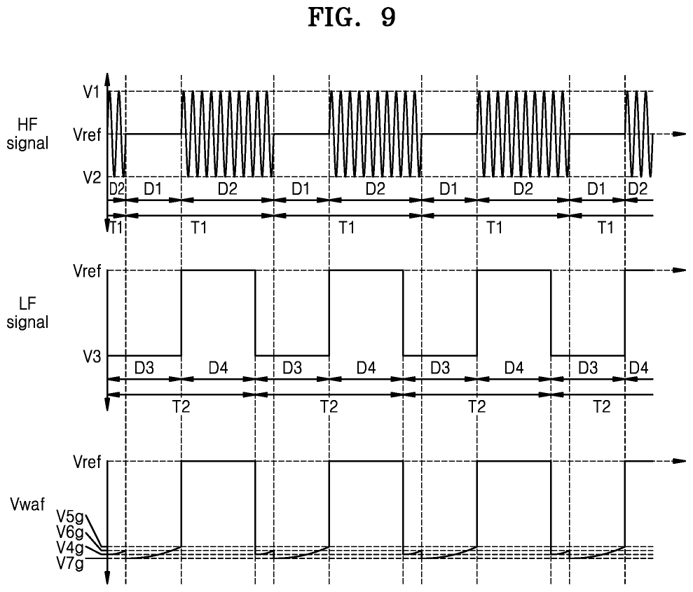

FIG. 9 is a graph illustrating an operation of a semiconductor processing apparatus according to example embodiments. The same descriptions as given with reference to FIGS. 1A and 3 to 8 will be omitted for brevity, and differences will chiefly be described.

Referring to FIG. 9, a first cycle T1 may be equal to a second cycle T2. According to example embodiments, a length of a first duration D1 may be different from a length of a second duration D2. According to example embodiments, the length of the first duration D1, which is an off duty of a high-frequency signal, may be less than the length of the second duration D2, which is an on duty of the high-frequency signal. The length of the first duration D1 may be less than a length of each of third and fourth durations D3 and D4. The length of the second duration D2 may be greater than the length of each of the third and fourth durations D3 and D4.

Referring to FIG. 9, the first duration D1, which is included in the third duration D3, may overlap the third duration D3 without overlapping the fourth duration D4. Thus, the high-frequency signal may be turned off and turned on while a non-sinusoidal low-frequency signal is maintained at a third voltage V3. Also, the high-frequency signal may not be turned off while the non-sinusoidal low-frequency signal is maintained at the reference voltage Vref. However, the inventive concept is not limited thereto. For example, depending on a phase of the high-frequency signal, the first duration D1 may be included in the fourth duration D4 or may overlap each of the third and fourth durations D3 and D4. When the first duration D1 overlaps each of the third and fourth durations D3 and D4, the first duration D1 may overlap a point in time when the transition from the third duration D3 to the fourth duration D4 occurs or overlap a point in time when the transition from the fourth duration D4 to the third duration D3 occurs.

According to example embodiments, a voltage applied to a substrate 100 may be maintained at the reference voltage Vref during the fourth duration D4. The voltage applied to the substrate 100 may increase from a fourth voltage V4g to a sixth voltage V6g during the third duration D3 overlapping the second duration D2. The fourth voltage V4g may be higher than the third voltage V3, but the inventive concept is not limited thereto.

According to example embodiments, the voltage applied to the substrate 100 may be discontinuously changed from the sixth voltage V6g to a seventh voltage V7g the moment the transition from the second duration D2 to the first duration D1 occurs. Also, the voltage applied to the substrate 100 may increase during the third duration D3. When the first duration D1 starts during the third duration D3, that is, when the application of the third voltage V3 starts, since the high-frequency signal is in a turn-off state, the voltage applied to the substrate 100 may be lower than the third voltage V3.

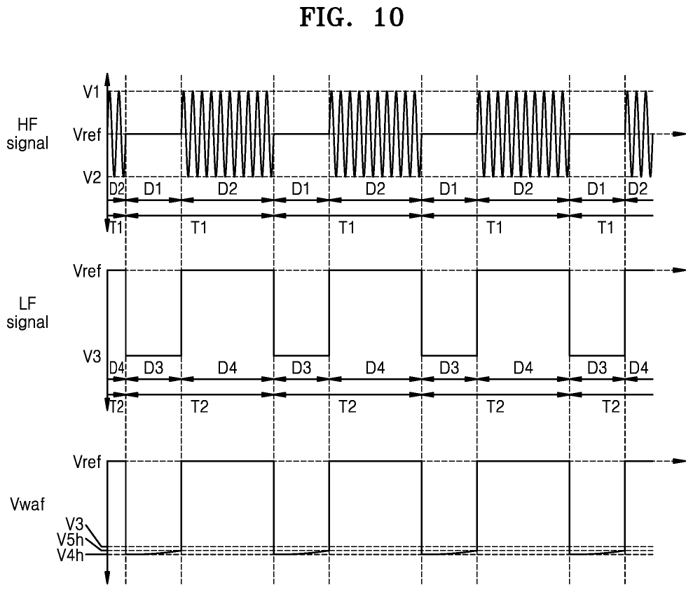

FIG. 10 is a graph illustrating an operation of a semiconductor processing apparatus according to example embodiments. The same descriptions as given with reference to FIGS. 1A and 3 to 9 will be omitted for brevity, and differences will chiefly be described.

A high-frequency signal of FIG. 10 may be substantially equal to the high-frequency signal described with reference to FIG. 9.

Referring to FIGS. 1A and 10, according to example embodiments, a length of a third duration D3 may be different from a length of a fourth duration D4. According to example embodiments, a length of the third duration D3 for which a non-sinusoidal low-frequency signal is maintained at a third voltage V3 may be less than a length of the fourth duration D4 for which the non-sinusoidal low-frequency signal is maintained at the reference voltage Vref.

According to example embodiments, the length of the third duration D3 is equal to a length of a first duration D1, and the length of the fourth duration D4 is equal to a length of a second duration D2.

Referring to FIG. 10, the first duration D1 may overlap the third duration D3 without overlapping the fourth duration D4, and the second duration D2 may overlap the fourth duration D4 without overlapping the third duration D3, but the inventive concept is not limited thereto. During the third duration D3, a voltage applied to a substrate 100 may be changed from a fourth voltage V4h to a fifth voltage V5h. According to example embodiments, since a duration for which the non-sinusoidal low-frequency signal is maintained at the third voltage V3 is relatively short, a variation in the voltage applied to the substrate 100 due to the accumulation of charges may be reduced. Thus, the voltage applied to the substrate 100 may have a waveform relatively close to a square wave.

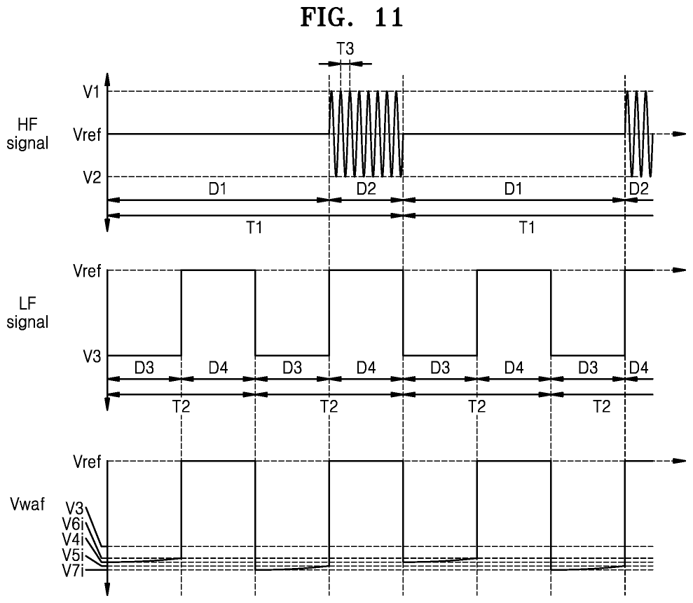

FIG. 11 is a graph illustrating an operation of a semiconductor processing apparatus according to example embodiments. The same descriptions as given with reference to FIGS. 1A and 3 to 10 will be omitted for brevity, and differences will chiefly be described.

Referring to FIGS. 1A and 11, a first cycle T1 may be different from a second cycle T2. According to example embodiments, the first cycle T1 may be greater than the second cycle T2. Although FIG. 11 illustrates a case in which the first cycle T1 is about twice the second cycle T2, the inventive concept is not limited thereto. For example, the first cycle T1 may be at least three times the second cycle T2 or may be an arbitrary integer multiple (e.g., 3:2) of the second cycle T2.

According to example embodiments, the high-frequency signal may be turned on and turned off at intervals of a first cycle T1. The high-frequency signal may be a sinusoidal voltage that varies between a first voltage V1 and a second voltage V2.

A length of a first duration D1 may be different from a length of a second duration D2. According to example embodiments, the length of the first duration D1 may be greater than the length of the second duration D2. During the the second duration D2, the high-frequency signal may have a sinusoidal voltage that varies at intervals of a third cycle T3. The third cycle may be 5 ns to 25 ns.

According to example embodiments, the first, second, and third cycles T1, T2, and T3 are different from each other.

FIG. 11 illustrates a case in which the length of the first duration D1 is about three times the length of each of the third and fourth durations D3 and D4 and the length of the second duration D2 is equal to the length of each of the third and fourth durations D3 and D4, but the inventive concept is not limited thereto. In addition, although the second duration D2 is illustrated as overlapping the fourth duration D4, the inventive concept is not limited thereto.

According to example embodiments, during the first cycle T1, a length of a duration for which a non-sinusoidal low-frequency signal is a third voltage V3 may be different from a length of a duration for which a high-frequency signal is turned on. According to example embodiments, during the first cycle T1, the length of the duration for which the non-sinusoidal low-frequency signal is the third voltage V3 may be greater than the length of the duration for which the high-frequency signal is turned on. According to example embodiments, during the first cycle T1, the length of the duration for which the non-sinusoidal low-frequency signal is the third voltage V3 may be an integral multiple of the length of the duration for which the high-frequency signal is turned on. According to example embodiments, the first cycle T1 may include two third durations D3 and one second duration D2. Thus, a ratio of a time duration for which the non-sinusoidal low-frequency signal is the third voltage V3 to a time duration for which the high-frequency signal is turned on may be about 2:1.

A voltage applied to a substrate 100 may be maintained at the reference voltage Vref during the fourth duration D4. The voltage applied to the substrate 100 may be changed from a fourth voltage V4i to a sixth voltage V6i or changed from a seventh voltage V7i to a fifth voltage V5i during the third duration D3. According to example embodiments, a cycle during which the voltage applied to the substrate 100 is changed may be the first cycle T1, which is longer than the second cycle T2. Since a process using plasma PLA is performed during the first duration D1, a concentration of the plasma PLA may be reduced, and thus, the seventh voltage V7i may be lower than the fourth voltage V4i. However, the inventive concept is not limited thereto, and the seventh voltage V7i may be equal to the fourth voltage V4i.

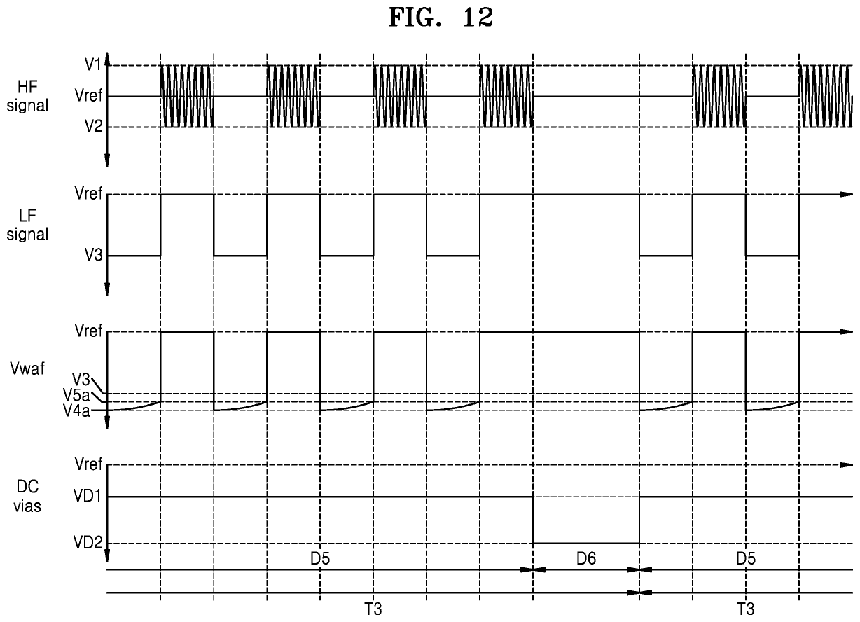

FIG. 12 is a graph illustrating an operation of a semiconductor processing apparatus according to example embodiments. The same descriptions as given with reference to FIGS. 1A and 3 will be omitted for brevity, and differences will chiefly be described.

Referring to FIG. 12, a high-frequency signal and a non-sinusoidal low-frequency signal may be the same as the high-frequency signal and the non-sinusoidal low-frequency signal described with reference to FIG. 3. A variation in DC signal (or DC bias) is illustrated by the lowest curve of FIG. 12. In FIG. 12, the abscissa denotes time and the ordinate denotes a voltage.

Referring to FIGS. 1 and 12, a third cycle T3, which is a cycle of the DC signal, may include a fifth duration D5 and a sixth duration D6. The DC signal may apply a first DC voltage VD1 to an upper electrode 530 during the fifth duration D5 and apply a second DC voltage VD2 to the upper electrode 530 during the sixth duration D6. Each of the first and second DC voltages VD1 and VD2 may be lower than a reference voltage Vref. In some examples, the reference voltage Vref is a ground voltage (e.g., 0 V) and each of the first and second DC voltages VD1 and VD2 is a negative voltage. The second DC voltage VD2 may be different from the first DC voltage VD1. The second DC voltage VD2 may be lower than the first DC voltage VD1.

According to example embodiments, the non-sinusoidal low-frequency signal and the high-frequency signal may be synchronized with the DC signal. According to example embodiments, the non-sinusoidal low-frequency signal and the high-frequency signal may be in a turn-on state and a turn-off state at a frequency during the fifth duration D5 and may be in a turn-off state during the sixth duration D6.

Cations in plasma PLA may collide with the upper electrode 530 due to each of the first and second DC voltages VD1 and VD2, which is a negative voltage, to generate secondary electrons, and the secondary electrons may be supplied into the substrate 100 due to the second DC voltage VD2. In some examples, the secondary electrons may be supplied into the substrate 100 due to the second DC voltage VD2 while the high-frequency signal is in a turn-off state. As a result, the cations accumulated in the substrate 100 may be neutralized by the secondary electrons.

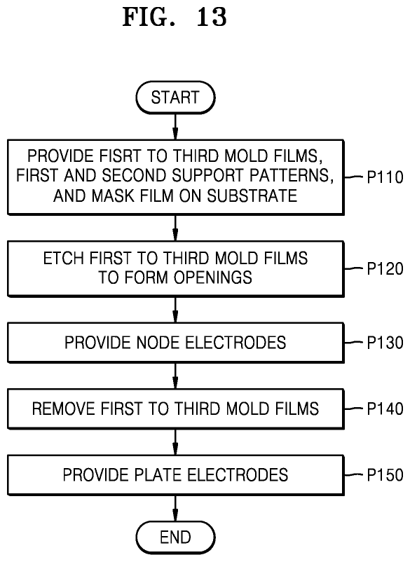

FIG. 13 is a flowchart illustrating a method of manufacturing a semiconductor device, according to example embodiments.

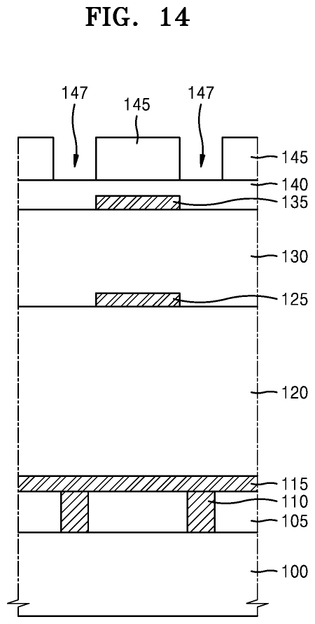

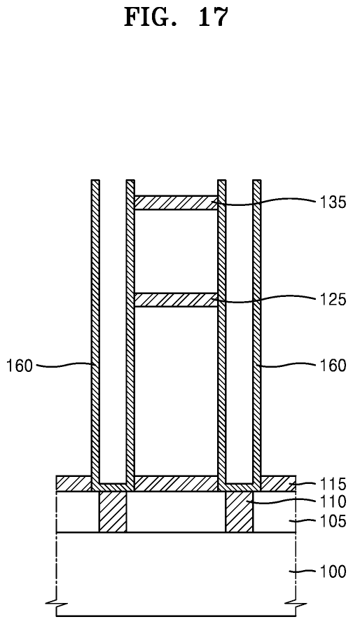

FIGS. 14 to 18 are cross-sectional views illustrating a method of manufacturing a semiconductor device, according to example embodiments.

Referring to FIGS. 13 and 14, in operation P110, first to third mold films 120, 130, and 140, first and second support patterns 125 and 135, and a mask film 145 may be formed on a substrate 100.

An interlayer insulating film 105 may be formed on the substrate 100 so that the interlayer insulating film 105 may cover a top surface of the substrate 100 and be in contact with the substrate 100. Contact plugs 110 may be formed to pass through the interlayer insulating film 105.

Thereafter, an etch stop film 115 and the first mold film 120 may be sequentially formed on the interlayer insulating film 105 and the contact plugs 110. The etch stop film 115 may include an insulating material having an etch selectivity with respect to the first mold film 120. The etch stop film 115 may include a silicon nitride film, and the first mold film 120 may include a silicon oxide film.

The first support pattern 125 may be formed on the first mold film 120. The first support pattern 125 may include an insulating material having an etch selectivity with respect to the first mold film 120. According to example embodiments, the first support pattern 125 may include silicon nitride.

The second mold film 130 may be formed on the first support pattern 125 and the first mold film 120. The second mold film 130 may include the same material (e.g., silicon oxide film) as the first mold film 120, but the inventive concept is not limited thereto.

The second support pattern 135 may be formed on the second mold film 130. The second support pattern 135 may overlap the first support pattern 125. The second support pattern 135 may include an insulating material having an etch selectivity with respect to the second mold film 130. For example, the second support pattern 135 may include silicon nitride. The third mold film 140 may be formed on the second support pattern 135 and the second mold film 130. The third mold film 140 may include the same material (e.g., silicon oxide film) as the second mold film 130, but the inventive concept is not limited thereto.

The mask film 145 having mask openings 147 may be formed on the third mold film 140. The mask film 145 may include at least one of a hard mask film (e.g., an amorphous carbon film or a polysilicon film) and a photoresist film.

Referring to FIGS. 1A, 13, and 15, the first to third mold films 120, 130, and 140 may be etched to form openings 150.

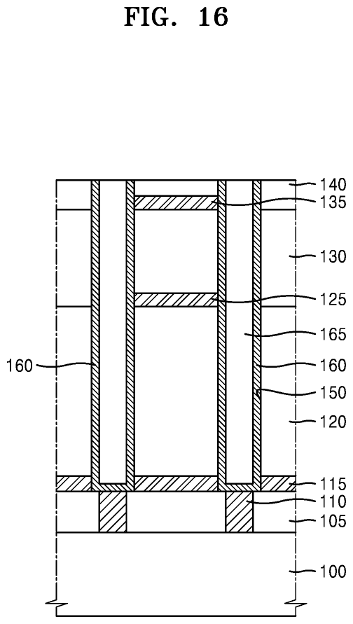

The first to third mold films 120, 130, and 140 may be etched using the mask film 145 as an etch mask, thereby forming the openings 150. The openings 150 may expose portions of the etch stop film 115 located on the contact plugs 110, respectively. The openings 150 may expose portions of side surfaces of the first and second support patterns 125 and 135. In some examples, the openings 150 may expose the contact plugs 110 by further etching the exposed portions of the etch stop film 115 using an additional etching process, as shown in FIG. 16.

According to an example embodiment, the first to third mold films 120, 130, and 140 may be etched using the semiconductor manufacturing apparatus 500 shown in FIG. 1A.

According to an example embodiment, the first to third mold films 120, 130, and 140 may be etched using any one of the semiconductor manufacturing apparatuses 500a, 500b, and 500c shown in FIGS. 2A to 2C.

The substrate 100 including the first to third mold films 120, 130, and 140 and the mask film 145 may be loaded on a lower electrode 520 in a process chamber 510. Thereafter, a process gas (i.e., an etch gas) may be supplied into the process chamber 510. For example, when a film to be etched includes silicon oxide and/or silicon nitride, the etch gas may include at least one of oxygen (O₂), fluorocarbons (e.g., C₄F₈ and/or C₄F₆), hydrofluorocarbons (e.g., CHF₃, CH₂F₂, and/or CH₃F), and NF₃. The etch gas may further include argon (Ar) gas that is used as a carrier gas.

According to example embodiments, each of a high-frequency signal generated by the high-frequency power generator 550 and a non-sinusoidal low-frequency signal generated by the low-frequency power generator 560 may have any one of the waveforms shown in FIGS. 3 to 12.

Ions having low energy may have a low linearity and move by a short distance. Thus, when openings formed by etching the first to third mold films 120, 130, and 140 are etched using plasma ions accelerated at low energy, a bowing phenomenon where a linewidth of a central portion of an etching profile is increased may occur.

According to example embodiments, an energy distribution of ions contained in plasma PLA may be uniform. According to example embodiments, the ions of the plasma PLA may be accelerated at high energy due to a relatively constant voltage, and a ratio of ions having low energy may be reduced. Thus, since the bowing phenomenon is prevented, the reliability of a semiconductor manufacturing process may be enhanced.

After the etching process is performed, a remaining mask film 145r may be removed.

Referring to FIGS. 13 and 16, in operation P130, node electrodes 160 may be provided.

The providing of the node electrodes 160 may include conformally forming a conductive material film on the substrate 100 having the openings 150 exposing the contact plugs 110, filling the inside of the conductive material film with a filling material film, and separating nodes by performing an etchback process using a top surface of the third mold film 140 as an etch stop point. Thus, the node electrodes 160 and filling patterns 165 may be provided. The filling patterns 165 may include polysilicon or silicon oxide.

The node electrodes 160 may include a semiconductor material (e.g., doped silicon), for example, at least one of a conductive metal nitride (e.g., titanium nitride or tantalum nitride), a metal material (e.g., tungsten, titanium, and tantalum), and a conductive metal oxide (e.g., iridium oxide).

Referring to FIGS. 13, 16, and 17, in operation P140, the first to third mold films 120, 130, and 140 may be removed.

According to some embodiments, the first to third mold films 120, 130, and 140 may be removed using a wet etching process. According to some embodiments, the first to third mold films 120, 130, and 140 may be etched using a material, which is etched at a higher rate than silicon oxide and etched at a lower rate than silicon nitride.

When the first to third mold films 120, 130, and 140 are removed, the filling patterns 165 may be also removed. Thus, surfaces of the node electrodes 160 may be exposed. In this case, the first and second support patterns 125 and 135 may not be etched but support the node electrodes 160 between the node electrodes 160.

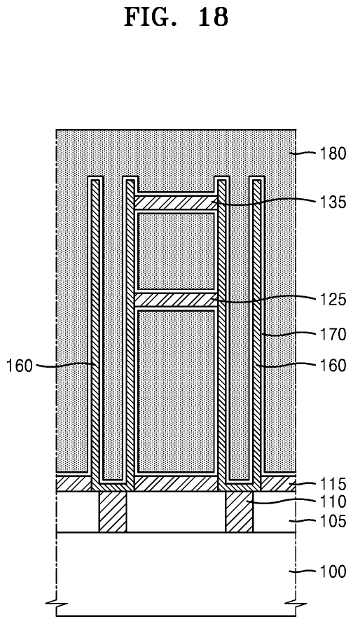

Referring to FIGS. 13 and 18, in operation P150, a plate electrode 180 may be provided.

According to some embodiments, a dielectric film 170 may be conformally formed on the surfaces of the node electrodes 160. In this case, the dielectric film 170 may be formed also on the exposed surfaces of the first and second support patterns 125 and 135. The dielectric film 170 may include a silicon oxide film, a silicon nitride film, or a high-dielectric film, for example, at least one insulating metal oxide, such as titanium oxide, tantalum oxide, hafnium oxide, and/or aluminum oxide.

The plate electrode 180 may be formed on the dielectric film 170 and cover the surfaces of the node electrodes 160. The plate electrode 180 may include at least one of materials described in relation to the node electrodes 160.

The node electrodes 160, the dielectric film 170, and the plate electrode 180 may constitute a capacitor. For example, the capacitor may constitute a portion of a unit cell of a dynamic random access memory (DRAM) device.

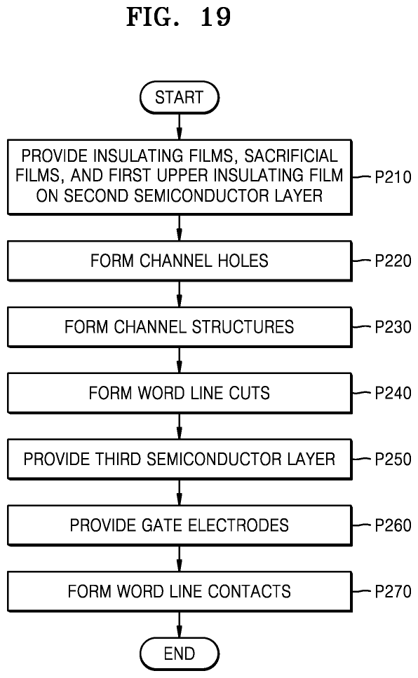

FIG. 19 is a flowchart illustrating a method of manufacturing a semiconductor device, according to example embodiments.

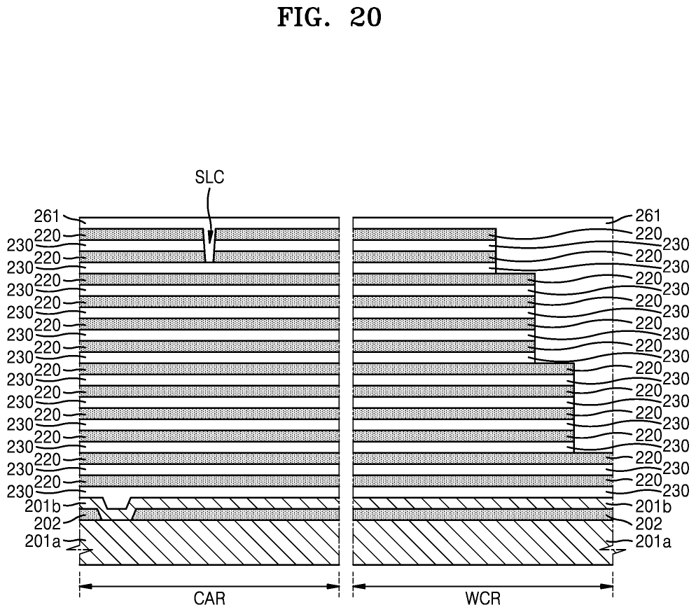

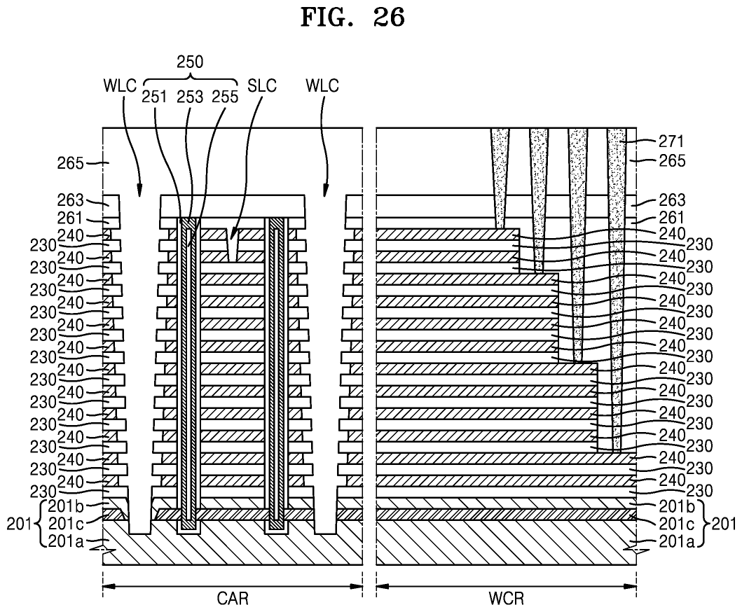

FIGS. 20 to 26 are schematic cross-sectional views illustrating a method of manufacturing a semiconductor device, according to example embodiments.

Referring to FIGS. 19 and 20, in operation P210, sacrificial films 220, insulating films 230, and a first upper insulating film 261 may be provided on a second semiconductor layer 201b.

A first semiconductor layer 201a, the second semiconductor layer 201b, and a sacrificial semiconductor layer 202 therebetween may be formed on a substrate (refer to 100 in FIG. 1A). According to example embodiments, for example, a conductive plate including tungsten may be provided between the substrate (refer to 100 in FIG. 1A) and the first semiconductor layer 201a, but the inventive concept is not limited thereto. In some cases, logic gates configured to drive a semiconductor device, interconnections configured to connect the logic gates, and a lower interlayer insulating film configured to cover the logic gates and the interconnections may be further provided between the conductive plate including tungsten and the substrate (refer to 100 in FIG. 1A). However, the inventive concept is not limited thereto, and a conductive plate may be directly provided on the substrate (refer to 100 in FIG. 1A), and logic gates configured to drive the semiconductor device may be arranged at a position apart from the conductive plate in a lateral direction.

The sacrificial semiconductor layer 202 may include an opening exposing a top surface of the first semiconductor layer 201a, and the second semiconductor layer 201b may be in contact with the first semiconductor layer 201a inside the opening.

A cell array region CAR including memory cells and a word line contact region WCR may be defined on the substrate (refer to 100 in FIG. 1A).

The insulating films 230 and the sacrificial films 220 may be alternately stacked. The sacrificial films 220 may include a material having an etch selectivity with respect to the insulating films 230. For example, when the insulating films 230 includes silicon oxide films, the sacrificial films 220 may include silicon nitride films. The sacrificial films 220 formed in the word line contact region WCR may be provided in a staircase form. For example, the sacrificial film 220 located at a lower level may protrude more than the sacrificial film 220 located at a higher level. For brevity of drawings, some of the sacrificial films 220 and insulating films 230 formed in the word line contact region WCR are not provided in a staircase form.

A string selection line cut SLC may be formed to separate the sacrificial films 220 located at an uppermost level and a second uppermost level, from among the sacrificial films 220, in the lateral direction. The first upper insulating film 261 may fill the string selection line cut SLC and cover the insulating films 230 and the sacrificial films 220.

Referring to FIGS. 1A, 19, and 21, in operation P220, channel holes CH may be formed.

According to an example embodiment, to form the channel holes CH, the substrate 100 may be loaded into the semiconductor processing apparatus 500.

According to an example embodiment, the channel holes CH may be formed using one of the semiconductor manufacturing apparatuses 500a, 500b, and 500c shown in FIGS. 2A to 2C.

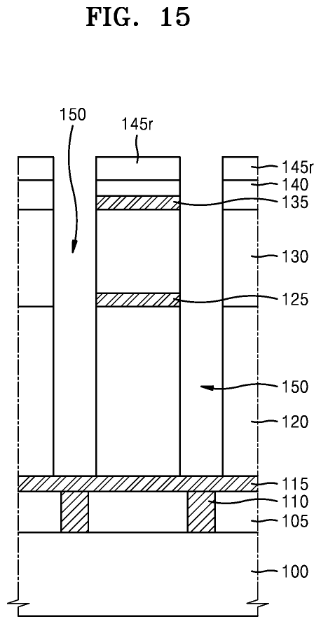

At least some of the etch gases described with reference to FIG. 15 may be provided to the inside of a process chamber 510, plasma PLA may be formed using a high-frequency signal generated by a high-frequency power generator 550, and ions contained in the plasma PLA may be accelerated using a non-sinusoidal low-frequency signal generated by the low-frequency power generator 560 to form the channel holes CH. The channel holes CH may pass through the first upper insulating film 261, the insulating films 230, the sacrificial films 220, the first and second semiconductor layers 201a and 201b, and the sacrificial semiconductor layer 202 in a vertical direction.

After the channel holes CH are formed, the substrate 100 may be unloaded from the semiconductor processing apparatus 500.

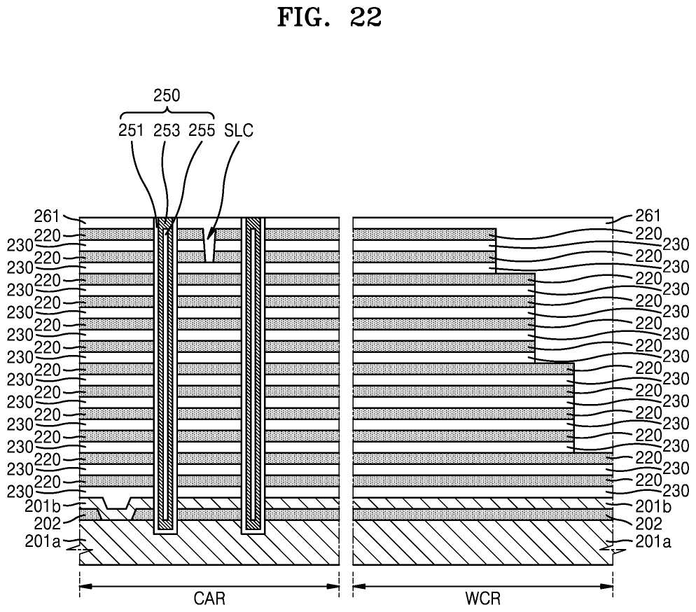

Referring to FIGS. 19 and 22, in operation P230, channel structures 250 may be formed.

Each of the channel structures 250 may include a gate insulating film 251, a channel layer 253, and a buried insulating film 255.

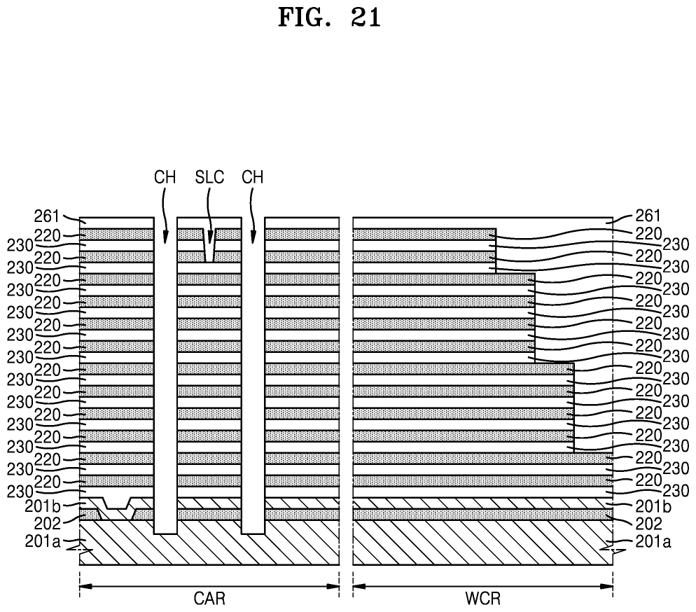

A gate insulating material film, a channel material film, and a buried insulating film may be sequentially and conformally provided to fill at least a portion of each of the channel holes (refer to CH in FIG. 21). According to some embodiments, the gate insulating material film may include a charge blocking material film, a charge storage material film, and a tunnel insulating material film, which are sequentially provided. Thereafter, an etchback process may be performed to expose a top surface of the first upper insulating film 261 so that the gate insulating material film, the channel material film, and the buried insulating film may be separated from each other.

Thereafter, an upper portion of the buried insulating material film may be further removed from the insides of the channel holes CH, and the same material as the channel material film may be deposited to cover an upper portion of the buried insulating film 255. Thus, pads may be formed to subsequently form contacts in the channel layer 253.

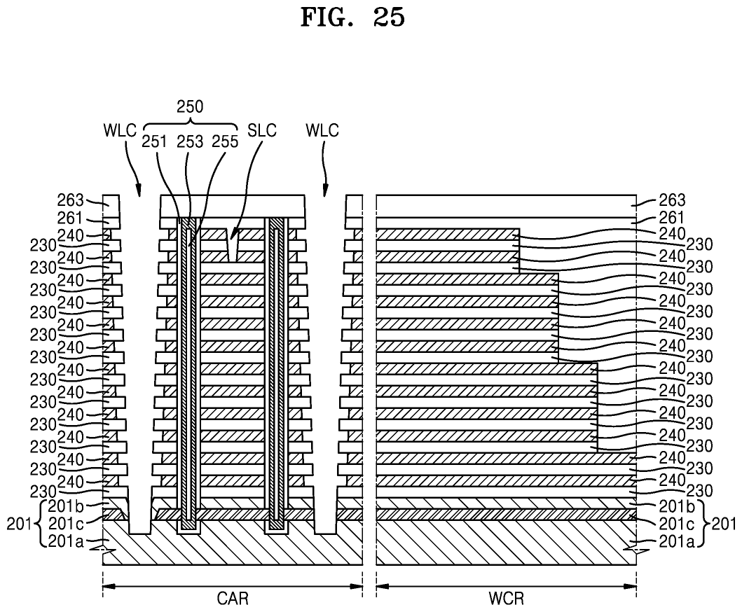

As a result, the channel structures 250 including the gate insulating film 251, the channel layer 253, and the buried insulating film 255 may be formed. The gate insulating film 251 may include a charge blocking film including silicon oxide, a charge storage film including silicon nitride, and a tunnel insulating film including silicon oxide. Charges passing through the channel layer 253 may tunnel the tunnel insulating film and be stored in the charge storage film. The charge blocking film may prevent the charges stored in the charge storage film from leaking into gate electrodes (refer to 240 in FIG. 25).

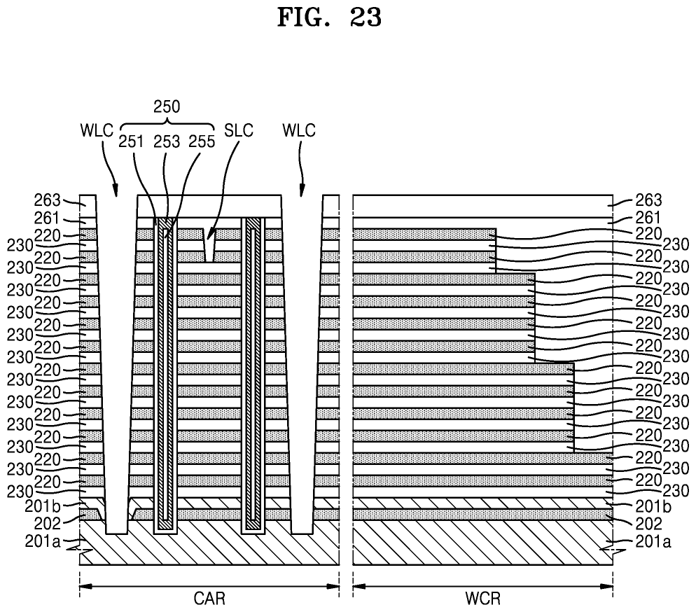

Referring to FIGS. 19 and 23, in operation P240, word line cuts WLC may be formed.

A second upper insulating film 263 and a hard mask pattern may be sequentially provided to cover top surfaces of the channel structures 250 and a top surface of the first upper insulating film 261. Afterwards, the first and second semiconductor layers 201a and 201b, the sacrificial semiconductor layer 202, the first and second upper insulating films 261 and 263, the sacrificial films 220, and the insulating films 230 may be etched using the hard mask pattern as an etch mask.

According to an example embodiment, to form the word line cuts WLC, the substrate 100 may be loaded into the semiconductor processing apparatus 500 shown in FIG. 1A.

According to an example embodiment, the word line cuts WLC may be formed using one of the semiconductor manufacturing apparatuses 500a, 500b, and 500c shown in FIGS. 2A to 2C.

After the word line cuts WLC are formed, the hard mask pattern may be removed. According to some embodiments, each of the word line cuts WLC may have a tapered shape in a vertical direction. According to some embodiments, the word line cuts WLC may extend in a long manner in the lateral direction and separate the sacrificial films 220, which are located at the same level, from each other in the lateral direction.

According to some embodiments, some of the word line cuts WLC may overlap the opening. According to some embodiments, some of the word line cuts WLC may extend in the vertical direction and pass through the opening. Thus, the word line cuts WLC may not pass through the sacrificial semiconductor layer 202.

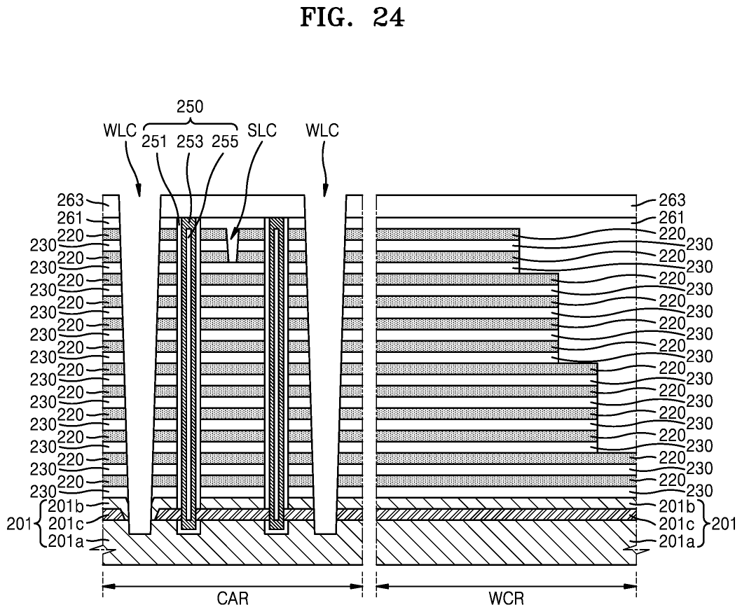

Referring to FIGS. 19 and 24, in operation P250, the third semiconductor layer 201c may be provided.

According to some embodiments, a word line cut liner may be provided to cover bottom surfaces and sidewalls of the word line cuts WLC, and a lower portion of the word line cut liner may be partially removed to expose the sacrificial semiconductor layer (refer to 202 in FIG. 23). The word line cut liner may protect the sacrificial films 220 during the removal of the sacrificial semiconductor layer (refer to 202 in FIG. 23).

Even if the sacrificial semiconductor layer (refer to 202 in FIG. 23) is removed, since the first semiconductor layer 201a and the second semiconductor layer 201b are connected to each other, the insulating films 230 and the sacrificial films 220 formed on the second semiconductor layer 201b may be prevented from collapsing.

Thereafter, a portion of the gate insulating film 251, which is located at the same level as the sacrificial semiconductor layer (refer to 202 in FIG. 23) may be removed, and the third semiconductor layer 201c may be provided. Thus, the third semiconductor layer 201c, which is connected to the channel layer 253, may be provided. The first to third semiconductor layers 201a, 201b, and 201c may constitute a semiconductor layer 201 and each include doped polysilicon.

Referring to FIGS. 19 and 25, in operation P260, gate electrodes 240 may be provided.

The providing of the gate electrodes 240 may include removing the sacrificial films (refer to 220 in FIG. 24) using a wet etching process, providing a gate electrode material film, and wet etching the gate electrode material film to separate nodes. Thus, the gate electrodes 240 adjacent to the word line cuts WLC may be recessed in a lateral direction. As a result, a plurality of gate electrodes 240 may be formed and separated from each other in a lateral direction. The plurality of gate electrodes 240, which are separated from each other in the lateral direction, may operate as gate electrodes of ground selection lines included in different strings, gate electrodes of different memory cells, or gate electrodes of string selection lines.

Referring to FIGS. 1, 19, and 26, in operation P270, word line contacts 271 may be formed.

To form the word line contacts 271, the substrate 100 may be loaded into the semiconductor processing apparatus 500.

The formation of the word line contacts 271 may include providing a third upper insulating film 265 to cover the word line cuts WLC and forming word line contact holes on the word line contact region WCR to expose portions of the gate electrodes 240.

According to an example embodiment, to form the word line contact holes, the substrate 100 may be loaded into the semiconductor processing apparatus 500 shown in FIG. 1A.

According to an example embodiment, the word line contact holes may be formed using one of the semiconductor manufacturing apparatuses 500a, 500b, and 500c shown in FIGS. 2A to 2C.

At least some of the etch gases described with reference to FIG. 15 may be provided to the inside of the process chamber 510, and plasma PLA may be formed using a high-frequency signal generated by the high-frequency power generator 550. Ions contained in the plasma PLA may be accelerated using a non-sinusoidal low-frequency signal generated by the low-frequency power generator 560 to form the word line contact holes.

Thereafter, a contact material layer may be provided to fill the word line contact holes, and the contact material layer may be separated using an etchback process. As a result, the word line contacts 271 may be formed to be in contact with the gate electrodes 240.

While the inventive concept has been particularly shown and described with reference to embodiments thereof, it will be understood that various changes in form and details may be made therein without departing from the spirit and scope of the following claims.

What is claimed is:

1. A semiconductor processing apparatus comprising:
a process chamber in which a semiconductor process is performed;
a lower electrode disposed inside the process chamber, the lower electrode having a top surface on which a substrate is loaded;
an upper electrode disposed on the lower electrode;
a first power generator configured to provide a low-frequency signal to the lower electrode, wherein the low-frequency signal varies between a reference voltage and a first voltage lower than the reference voltage at intervals of a first cycle;
a second power generator configured to provide a high-frequency signal to the lower electrode, wherein the high-frequency signal has a sinusoidal waveform that oscillates at intervals of a second cycle shorter than the first cycle; and
a direct-current (DC) power generator configured to provide a DC bias to the upper electrode, wherein the DC bias is lower than the reference voltage,
wherein the high-frequency signal is turned off during at least part of a duration for which the low-frequency signal has the first voltage, and
wherein the high-frequency signal is turned on and turned off at intervals of a third cycle different from the first and second cycles.

2. The semiconductor processing apparatus of claim 1, wherein the third cycle is longer than the first cycle.

3. The semiconductor processing apparatus of claim 1, wherein the third cycle is at least twice the first cycle.

4. The semiconductor processing apparatus of claim 1, wherein the third cycle is an integral multiple of the first cycle.

5. The semiconductor processing apparatus of claim 1, wherein the high-frequency signal is turned on when the low-frequency signal is changed from the first voltage to the reference voltage, and turned off when the low-frequency signal is changed from the reference voltage to the first voltage.

6. The semiconductor processing apparatus of claim 1, wherein the high-frequency signal is turned on while the low-frequency signal is maintained at the reference voltage, and turned off while the low-frequency signal is maintained at the first voltage.

7. The semiconductor processing apparatus of claim 1, wherein, at intervals of the third cycle, a duration for which the high-frequency signal is turned on is shorter than a duration for which the low-frequency signal is maintained at the first voltage.

8. The semiconductor processing apparatus of claim 1, wherein the DC bias varies at intervals of a fourth cycle between a third voltage and a fourth voltage, and
wherein the fourth cycle is longer than the third cycle.

9. The semiconductor processing apparatus of claim 8, wherein, when the DC bias is the third voltage, the high-frequency signal and the low-frequency signal are turned on and turned off at a frequency.

10. The semiconductor processing apparatus of claim 8, wherein, when the DC bias is the fourth voltage lower than the third voltage, the high-frequency signal and the low-frequency signal are turned off.

11. The semiconductor processing apparatus of claim 1, wherein the semiconductor process includes an etching process using plasma ions.

12. The semiconductor processing apparatus of claim 11, wherein the second power generator is configured to generate the high-frequency signal such that the high-frequency signal generates plasma ions, and
wherein the first power generator is configured to generate the low-frequency signal such that the low-frequency signal accelerates the plasma ions.

13. The semiconductor processing apparatus of claim 1, wherein the third cycle is 25 ns or less, and the first cycle ranges from about 0.33 μs to about 10 μs.

14. A semiconductor processing apparatus comprising:
a process chamber having an inner space configured to perform a process using plasma;
a lower electrode located inside the process chamber, the lower electrode having a top surface configured to mount a substrate thereon;
an upper electrode located on the lower electrode;
a first power generator configured to provide, over a first cycle, a reference voltage to the lower electrode during a first duration and provide a radio-frequency (RF) sinusoidal signal to the lower electrode during a second duration;
a second power generator configured to provide, over a second cycle, a first voltage to the lower electrode during a third duration and provide the reference voltage to the lower electrode during a fourth duration; and
a direct-current (DC) power generator configured to apply a DC bias to the upper electrode, wherein the DC bias is lower than the reference voltage,
wherein the first cycle is repeated,
wherein the second cycle is repeated, and
wherein the second duration overlaps about 4% to 95% of the fourth duration.

15. The semiconductor processing apparatus of claim 14, wherein the second duration starts during the fourth duration.

16. The semiconductor processing apparatus of claim 14, wherein the second duration ends during the third duration.

17. The semiconductor processing apparatus of claim 14, wherein a length of each of the first and second durations is different from a length of the third duration.

18. The semiconductor processing apparatus of claim 14, wherein the first, second, third, and fourth durations have the same length as each other.

19. The semiconductor processing apparatus of claim 14, wherein the sum of lengths of the first and second durations ranges from about 0.33 μs to about 10 μs.

20. A semiconductor processing apparatus comprising:
a process chamber in which a semiconductor etching process is performed;
a lower electrode disposed inside the process chamber, the lower electrode having a top surface on which a substrate is loaded;
an upper electrode disposed on the lower electrode;
a first power generator configured to provide a high-frequency signal to the lower electrode, the high-frequency signal turned off during a first duration and turned on during a second duration;
a second power generator configured to provide a low-frequency signal to the lower electrode, the low-frequency signal turned on during a third duration and turned off during a fourth duration; and
a direct-current (DC) power generator configured to provide a DC bias to the upper electrode, wherein the DC bias is lower than a reference voltage,
wherein the first power generator is configured to provide a reference voltage to the lower electrode during the first duration and provide the high-frequency signal to the lower electrode during the second duration,
wherein the second power generator is configured to provide a first voltage lower than the reference voltage to the lower electrode during the third duration and provide the reference voltage to the lower electrode during the fourth duration, and
wherein the first duration is synchronous with the third duration and a length of the first duration is the same as a length of the third duration.
